(19) United States
(12) Patent Application Publication
(10) Pub. No.: US 2017/0192036 A1
(43) Pub. Date: Jul. 6, 2017

(54) PROBE STRUCTURE AND PROBE DEVICE

(71) Applicant: MPI Corporation, Chu-pei City (TW)

(72) Inventors: Yi-Chien Tsai, Chu-pei City (TW); Yi-Lung Lee, Chu-pei City (TW); Horng-Kuang Fan, Chu-pei City (TW)

(21) Appl. No.: 15/334,477

(22) Filed: Oct. 26, 2016

(30) Foreign Application Priority Data
Dec. 31, 2015 (TW) 104144813

(51) Int. Cl. G01R 1/067; G01R 31/28

(52) U.S. Cl. CPC G01R 1/06722; G01R 31/2884; G01R 1/06733

(57) ABSTRACT

A probe structure includes a tube body and a pin body. The tube body has a central axis and includes a first rigid section, a first spring section, a second rigid section, and a second spring section. The first spring section surrounds the central axis and extends in a direction along the central axis. Two ends of the first spring section connect to one end of the first rigid section and one end of the second rigid section. The first spring section and the second spring section are different in spring constant. The pin body passes through and is disposed in the tube body. The pin body has a head section protruding out of the first rigid section, and the head section is fastened to the first rigid section.

### CROSS-REFERENCE TO RELATED APPLICATION

This non-provisional application claims priority under 35 U.S.C. §119(a) to Patent Application No. 104144813 filed in Taiwan, R.O.C. on Dec. 31, 2015, the entire contents of which are hereby incorporated by reference.

### BACKGROUND

Technical Field

The instant disclosure relates to a probe structure and a probe device, in particular, to a probe structure and a probe device suitable for wafer testing in semiconductor industries.

Related Art

In the testing procedures for integrated circuit (IC) chips, a tester is electrically connected with an IC chip to be tested by a probe card. The test result of the IC chip can be obtained by signal transmission and signal analysis. A conventional probe card commonly includes a circuit board and a probe device, or the conventional probe card may further include a space transformer between the circuit board and the probe device. The probe device includes several probes corresponding to electrical contacts of the IC chip to be tested, so that the probes can be in contact with the electrical contacts at the same time.

FIGS. 1 and 2 respectively illustrate an exploded view of a conventional probe structure 11 and a partial sectional view of a conventional probe card 14. The conventional probe structure 11 includes a pin body 12 and an spring sleeve 13 fitting over the pin body 12. The spring sleeve 13 has two spring sections 138 separated by a non-spring section. The conventional probe card 14 includes a circuit plate 15 and a probe device 16. The circuit plate 15 may be a circuit board or a space transformer. The probe device 16 includes a probe holder 17 and a plurality of probe structures 11. In FIG. 2, for the sake of convenience in description, parts of the circuit plate 15, the probe holder 17, and one probe structure 11 are illustrated.

Upon the assembling of the probe structure 11, the pin body 12 is inserted into the spring sleeve 13. Then, a combination portion 132 at one end of the spring sleeve 13 is fastened with the pin body 12 by compression and welding procedures. The combination portion 132 has two protrusions 134 formed during the compression and welding procedures. Each of the protrusions 134 is protruding from an outer tube surface 136 of an uncompressed portion of the spring sleeve 13.

The probe holder 17 includes an upper guiding plate 171, a middle guiding plate 172, and a lower guiding plate 173 (or the probe holder 17 may include an upper guiding plate 171 and a lower guiding plate 173 and exclude from a middle guiding plate 172). The upper guiding plate 171, the middle guiding plate 172, and the lower guiding plate 173 are stacked with each other along a vertical direction and define several assembling holes 174, so that the probe structures 11 can be assembled in the assembling holes (In FIG. 2, one assembling hole 174 is shown). The assembling hole 174 is configured to be a round hole and the radius of the assembling hole 174 should be greater than a maximum distance between each of the protrusions 134 and the center of the probe structure 11, so that the probe structure 11 can be assembled into the assembling hole 174 from a top surface 175 of the probe holder 17, and the probe structure 11 can be rotated freely in the assembling hole 174 upon contacting the IC chip during the testing procedure.

When the probe device 16 is assembled, the circuit plate 15 is then positioned on the top surface 175 of the probe holder 17. Next, a top of the spring sleeve 13 is electrically connected to an electrical contact of the circuit plate 15, and a bottom of the pin body 12 is provided for contacting an electrical contact of a component to be tested. The spring sleeve 13 has the two spring sections 138 that are elastically compressible, a lower portion of the pin body 12 is fastened with the combination portion 132 at the lower end of the spring sleeve 13, and a gap 18 is between the top of the pin body 12 and the circuit plate 15 (i.e., the top of the spring sleeve 13). Therefore, when the bottom of the pin body 12 is abutted against the electrical contact of a component to be tested, the pin body 12 is retracted and the spring sleeve 13 is compressed. Accordingly, not only the probe structure 11 can be firmly in contact with and conducted with the electrical contact of the component to be tested, but also the electrical contacts of the component or the pin body 12 can be prevented from being damaged or excessively worn by the buffering function of the spring sleeve 13.

Please refer to FIG. 3. When the assembling of the probe device 16 is done, the spring sleeve 13 is compressed by a length of x1, and the corresponding elastic force of the spring sleeve 13 in such condition is f1. When the tip of the pin body 12 (i.e., the bottom of the pin body 12) slightly penetrates the surface of the pad (i.e., the electrical contact) of a component to be tested in a probing testing state, the spring sleeve 13 is compressed by a length of x2, and the corresponding elastic force of the spring sleeve 13 in such condition increases from f1 to f2.

The compressible stroke of each of the two spring sections 138 of the spring sleeve 13 of the conventional probe structure 11 is further greater than a prepressing stroke required by the probe structure 11 upon the probe structure 11 is assembled with the probe holder 17 and the circuit plate 15 plus a compression stroke of the pin body 12 caused upon the pin body 12 is forced against a surface of the pad. In other words, during the probe testing step, the two spring sections 138 of the spring sleeve 13 can be compressed freely. Therefore, the relationship between the force F the pin body 12 applies to the surface of the pad and the compression X of the spring sleeve 13 is linear, as shown in FIG. 3. The slope of the line shown in FIG. 3 is the equivalent spring constant of the two spring sections 138. For example, the spring constant (or called as Young's modulus) of the two spring sections 138 are respectively Kx and Ky, and the two spring sections 138 are in a series connection. Therefore, the equivalent spring constant of the two spring sections 138 is

$$Ke = \frac{{K}_{x} {K}_{y}}{{K}_{x} + {K}_{y}} .$$

The aforementioned prepressing procedure is provided for improving the flatness between the tips of the pin bodies 12 after the assembling step, i.e., allowing the tips of the pin bodies 12 to be on the same horizontal plane. Moreover, the spring constant of the spring sleeve 13 should not be too large; otherwise, the probe holder 17 may become warped after the prepressing procedure. However, in the probe testing step, the tip of the pin body 12 has to penetrate into the oxidized layer on the surface of the pad of the component to be tested. As a result, once the spring constant of the spring sleeve 13 is not large enough, the spring sleeve 13 has to be compressed by a longer stroke to provide a sufficient spring force and allow the tip of the pin body 12 penetrating into the oxidized layer on the surface of the pad. Conversely, when the spring constant of the spring sleeve 13 is large enough, once the spring sleeve 13 is slightly compressed, the spring sleeve 13 would provide a sufficient spring force to make the tip of the pin body 12 penetrate into the oxidized layer on the surface of the pad. In other words, the preference of the spring constant required in the prepressing procedure is just opposite from the preference of the spring constant required in the probe testing step.

### SUMMARY

In view of these issues, in one embodiment, a probe structure comprises a tube body having a central axis and a pin body passing through and disposed in the tube body. The tube body comprises a first rigid section, a first spring section, a second rigid section, and a second spring section. The first spring section surrounds the central axis and extends in a direction along the central axis. One of two ends of the first spring section is connected to one end of the first rigid section. One of two ends of the second rigid section is connected to the other end of the first spring section. The second spring section surrounds the central axis and extends in the direction along the central axis. One of two ends of the second spring section is connected to the other end of the second rigid section. The first spring section and the second spring section are different in spring constant. The pin body has a head section protruding from the first rigid section, and the head section is fastened to the first rigid section.

In another embodiment, a probe structure comprises a tube body having a central axis and comprising an spring section. The spring section surrounds the central axis and extends in a direction along the central axis. The spring section comprises a plurality of first curled portions and a plurality of second curled portions. The first curled portions and the second curled portions are in a series connection and arranged alternately. A first distance between two ends of the first curled portion along the central axis is less than a second distance between one of the second curled portions along the central axis.

In yet another embodiment, a probe device comprises a probe holder and a probe structure comprising the tube body and the pin body. The probe holder comprises an upper surface, a lower surface, and a guiding channel. The guiding channel is defined through the probe holder from the upper surface to the lower surface. A connection between the guiding channel and the lower surface forms a neck section. The probe structure is received in the guiding channel. An outer diameter of the first rigid section of the tube body is greater than an inner diameter of the neck section, so that the first rigid section is abutted against the neck section, and the head section of the pin body is protruding out of the lower surface.

### BRIEF DESCRIPTION OF THE DRAWINGS

The disclosure will become more fully understood from the detailed description given herein below for illustration only, and thus not limitative of the disclosure, wherein:

FIG. 1 illustrates an exploded view of a conventional probe structure;

FIG. 2 illustrates a partial sectional view of a conventional probe card;

FIG. 3 illustrates a diagram showing the relationship between force (F) and compression stroke (X) of the conventional probe structure;

FIG. 4 illustrates a schematic view of a probe structure according to a first embodiment of the instant disclosure;

FIG. 5 illustrates a partial enlarged view of the portion 5 shown in FIG. 4;

FIG. 6 illustrates a partial enlarged view of the portion 6 shown in FIG. 4;

FIG. 7A illustrates a side view of a first spring section of the probe structure of the first embodiment;

FIG. 7B illustrates a developed view of one of first curled portions of the first embodiment;

FIG. 7C illustrates a developed view of one of second curled portions of the first embodiment;

FIG. 8 illustrates a schematic view (1) of a probe structure according to a second embodiment of the instant disclosure;

FIG. 9 illustrates a schematic view (2) of the probe structure of the second embodiment;

FIG. 10 illustrates a partial sectional view of a probe device according to a third embodiment of the instant disclosure;

FIG. 11 illustrates a schematic view of a probe structure according to a fourth embodiment of the instant disclosure;

FIG. 12 illustrates a schematic view (1) of a probe structure according to a fifth embodiment of the instant disclosure;

FIG. 13 illustrates a schematic view (2) of the probe structure of the fifth embodiment;

FIG. 14 illustrates a diagram showing the relationship between force (F) and compression stroke (X) of the probe structure according to the instant disclosure;

FIG. 15 illustrates a schematic view (1) of a probe structure according to a sixth embodiment of the instant disclosure; and

FIG. 16 illustrates a schematic view (2) of the probe structure of the sixth embodiment.

### DETAILED DESCRIPTION

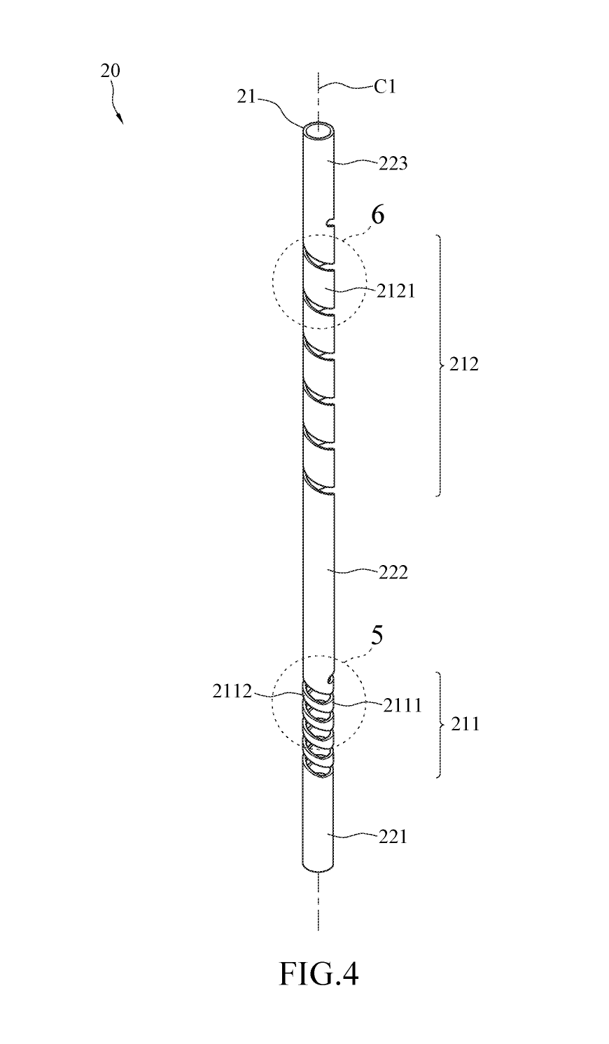

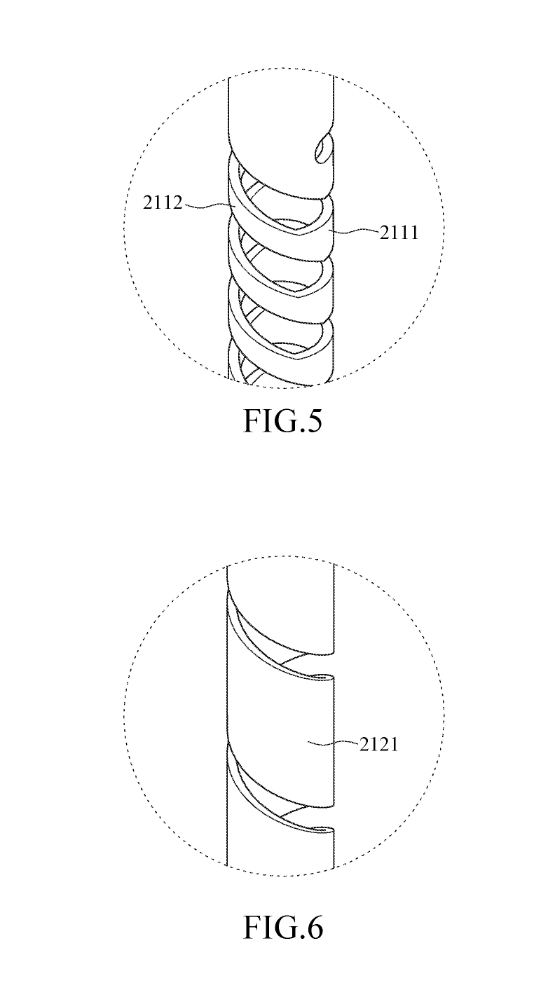

FIGS. 4 to 7C respectively illustrate a schematic view of a probe structure 20 according to a first embodiment of the instant disclosure, a partial enlarged view of the portion 5 shown in FIG. 4, a partial enlarged view of the portion 6 shown in FIG. 4, a side view of a first spring section 211 of the probe structure 20 of the first embodiment, a developed view of one of first curled portions 2111 of the probe structure 20 of the first embodiment, and a developed view of one of second curled portions 2112 of the probe structure 20 of the first embodiment. In this embodiment, the probe structure 20 comprises a tube body 21 having a central axis C1. The tube body 21 can be divided into, from one end to the other end, a first rigid section 221, a first spring section 211, a second rigid section 222, a second spring section 212, and a third rigid section 223.

The first spring section 211 comprises a plurality of first curled portions 2111 and a plurality of second curled portions 2112. The first curled portions 2111 and the second curled portions 2112 are in a series connection in a head-to-tail manner and arranged alternately to form the first spring section 211. The first spring section 211 surrounds the central axis C1 and extends in a direction along the central axis C1. One of two ends of the first rigid section 221 is connected to one of two ends of the first spring section 211, and the other end of the first rigid section 221 is a free end. Two ends of the second rigid section 222 are respectively connected to the other end of the first spring section 211 and one of two ends of the second spring section 212. One of two ends of the third rigid section 223 is connected to the other end of the second spring section 212, and the other end of the third rigid section 223 is a free end.

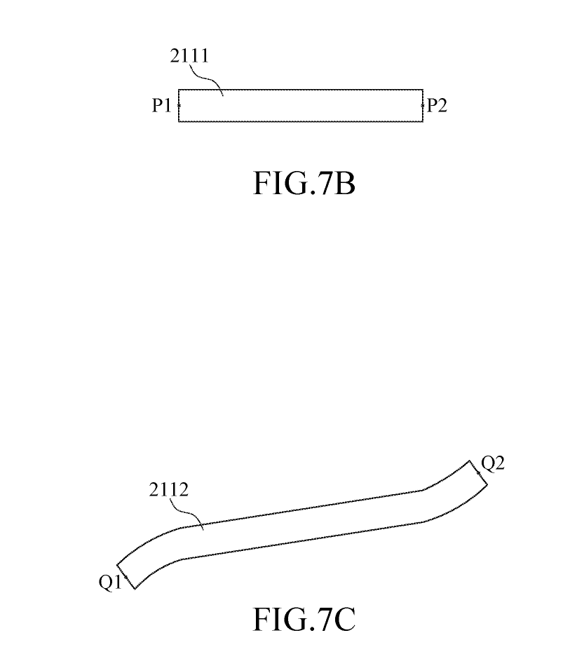

A first distance between two ends of one of the first curled portions 2111 along the central axis C1 is less than a second distance W2 between two ends of one of the second curled portions 2112 along the central axis C1. In this embodiment, the first distance is zero, the second distance W2 is not equal to zero, and the first distance is not indicated by numerical. When the first distance is zero, the first curled portion 2111 surrounds the central axis C1 on the same plane rather than extending in a direction along the central axis C1. As shown in FIG. 7A, the first curled portion 2111 substantially surrounds, from top view, a half circle of the central axis C1. The central points at two ends of the first curled portion 2111 are respectively P1 and P2, and the vector formed by the connection of the two points P1, P2 does not have components in the direction along the central axis C1. Namely, the first distance is zero. Likewise, when the second curled portion 2112 surrounds the central axis C1, the central points at two ends of the second curled portion 2112 are respectively Q1 and Q2, and the absolute value of the component of the vector formed by the connection of the two points Q1, Q2 in the direction along the central axis C1 is the second distance. As shown in FIGS. 7B and 7C, when the first curled portion 2111 and the second curled portion 2112 are developed and flattened, the first curled portion 2111 is linear, but the second curled portion 2112 is curved or includes curved and linear patterns.

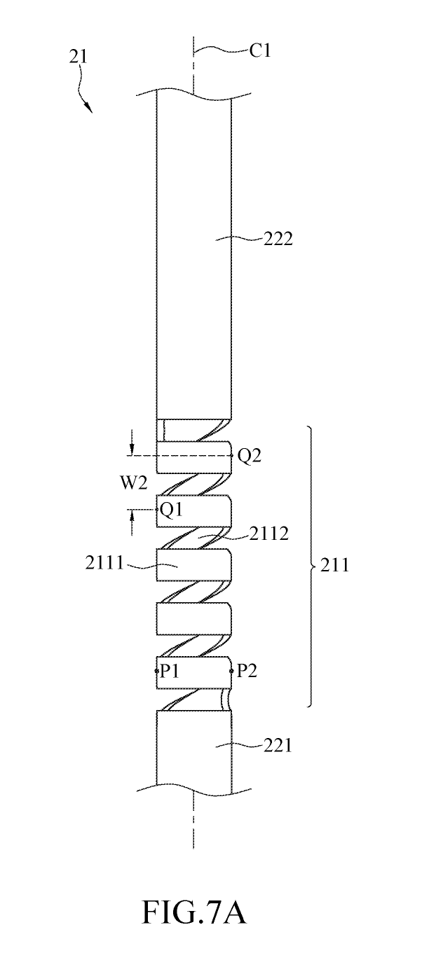

As shown in FIGS. 4 and 6, the second spring section 212 comprises a plurality of third curled portions 2121. The third curled portions 2121 surround the central axis C1 and extend in the direction along the central axis C1, and each of the third curled portions 2121 substantially surrounds a full circle of the central axis C1. In this embodiment, the spring constant of the second spring section 212 is greater than the spring constant of the first spring section 211.

As illustrated by a side view of the first spring section 211 shown in FIG. 7, the first curled portion 2111 is a horizontal line, meaning that the component of the vector formed by the connection of the central points P1, P2 at two ends of the first curled portion 2111 in the direction along the central axis C1, i.e., the first distance, is zero. The component of the vector formed by the connection of the central points Q1, Q2 at two ends of the second curled portion 2112 in the direction along the central axis C1, i.e., the second distance W2, is nonzero. In other words, in the side view of the first spring section 211, the slope of the first curled portion 2111 is zero, while the slope of the second curled portion 212 is greater than zero. In this embodiment, the first distance is configured as zero for illustrative purpose, but embodiments are not limited thereto. It is understood that, in this embodiment, the value of the component of the vector formed by the connection of the central pointes P1, P2 at two ends of the first curled portion 2111 in the direction along the central axis C1 is different from the value of the component of the vector formed by the connection of the central points Q1, Q2 at two ends of the second curled portion 2112 in the direction along the central axis C1.

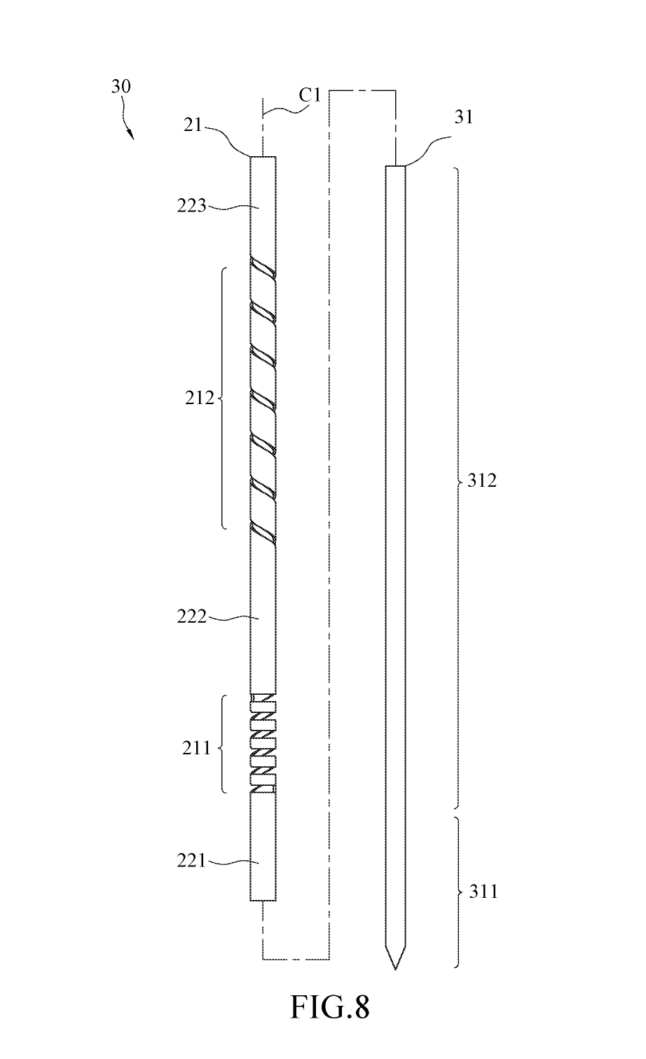

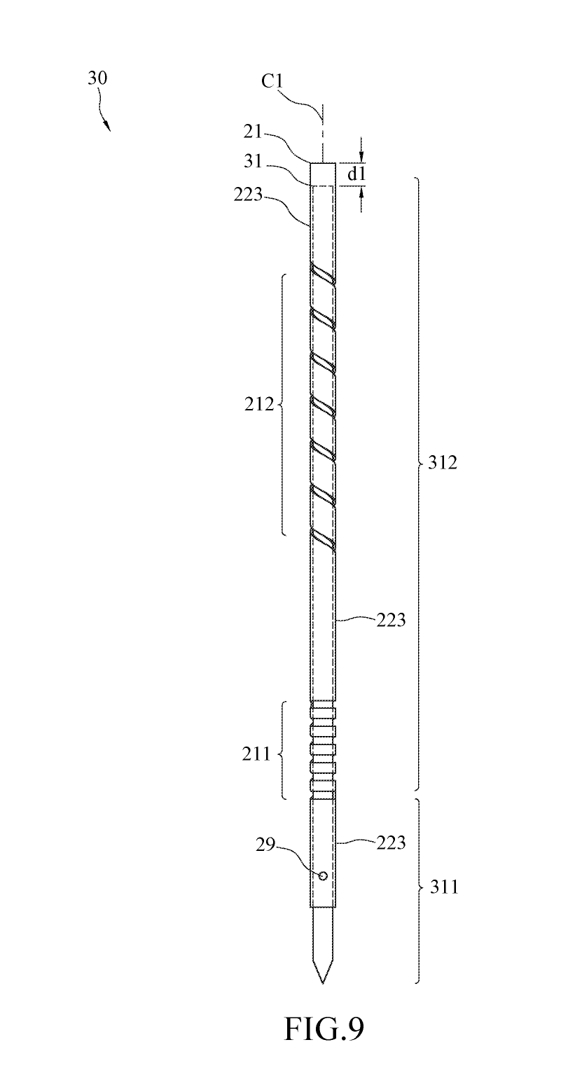

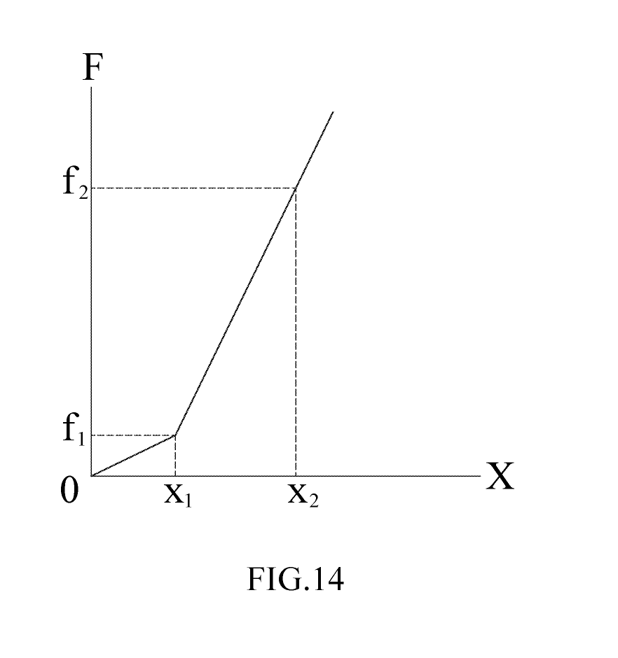

Please refer to FIGS. 8, 9, and 14. FIGS. 8 and 9 respectively illustrate schematic views (1), (2) of a probe structure 30 according to a second embodiment of the instant disclosure, and FIG. 14 illustrates a diagram showing the relationship between force (F) and compression stroke (X) of the probe structure according to the instant disclosure. In the second embodiment, the probe structure 30 further comprises a pin body 31. The pin body 31 is passing through the tube body 21, and the pin body 31 is disposed in the tube body 21. The pin body 31 has a head section 311 and a tail section 312. The head section 311 is protruding from the first rigid section 221 of the tube body 21, an end surface of the tail section 312 is lower than the third rigid section 223 of the tube body 21 by a distance d1. As shown in FIG. 9, in this embodiment, the head section 311 of the pin body 31 is fastened with the first rigid section 221 of the tube body 21 by compression and welding to form a fastening portion 29.

In this embodiment, when the probe structure 30 is further installed to a testing device, the tube body 21 is in a state that the tube body 21 is pre-compressed by a stroke of X1. When the tube body 21 is pre-compressed by a stroke of X1, the first spring section 211 is compressed to be in a state that the first spring section 211 cannot be compressed anymore and reaches or almost reaches to its dead point. In this embodiment, the first spring section 211 has two different curled portions, thus, a probe designer can design the first spring section 211 with proper spring constant easily. Accordingly, during the prepressing procedure, the probe structure 30 would not suffer severe buckling and become damaged. During the prepressing procedure of the assembling step, the compression performed by the tube body 21 and a behavior of an external force are determined by an equivalent spring constant Kₑ deduced from the spring constant K₁ of the first spring section 211 and the spring constant K₂ of the second spring section 212, wherein

$$Ke = \frac{{K}_{1} {K}_{2}}{{K}_{1} + {K}_{2}} .$$

In one embodiment, K₂ is ten times or more over K₁.

During the probe testing step, the tube body 21 is further pressed (i.e., the pin body 31 is further pressed downward). Because the first spring section 211 is compressed to be in a state that the first spring section 211 cannot be compressed anymore and reaches or almost reaches to its dead point, the compression performed by the tube body 21 and the behavior of the external force in the probe testing step are determined by the spring constant K₂ of the second spring section 212. Supposed that the total compressible stroke of the first spring section 211 is X1, when the first spring section 211 is prepressed by an extent greater than 90% of a force corresponding to a stroke of X1, yet the compression stroke is not reached to X1, the first spring section 211 is in the state that it almost reaches to its dead point. Therefore, combining the prepressing stage in the assembling step with the pressing stage in the probe testing step, the relationship between the force F suffered by the tube body 21 and the compression X of the tube body 21 is not linear; instead, as shown in FIG. 14, the line indicating the relationship between F and X has two different slopes. The compression X1 shown in FIG. 14 equals to the compression of the first spring section 211 upon being compressed to its dead point, and the slope of line corresponding to such instance is

$$\frac{{K}_{1} {K}_{2}}{{K}_{1} + {K}_{2}} .$$

The slope of the other line is K₂. While in the prepressing stage, the first spring section 211 is in the state that it almost reaches to its dead point. Therefore, in an early period of the probe testing step, the slope of the line is still

$$\frac{{K}_{1} {K}_{2}}{{K}_{1} + {K}_{2}} ,$$

and the slope of the line is changed into K₂ until the first spring section 211 is compressed to its dead point.

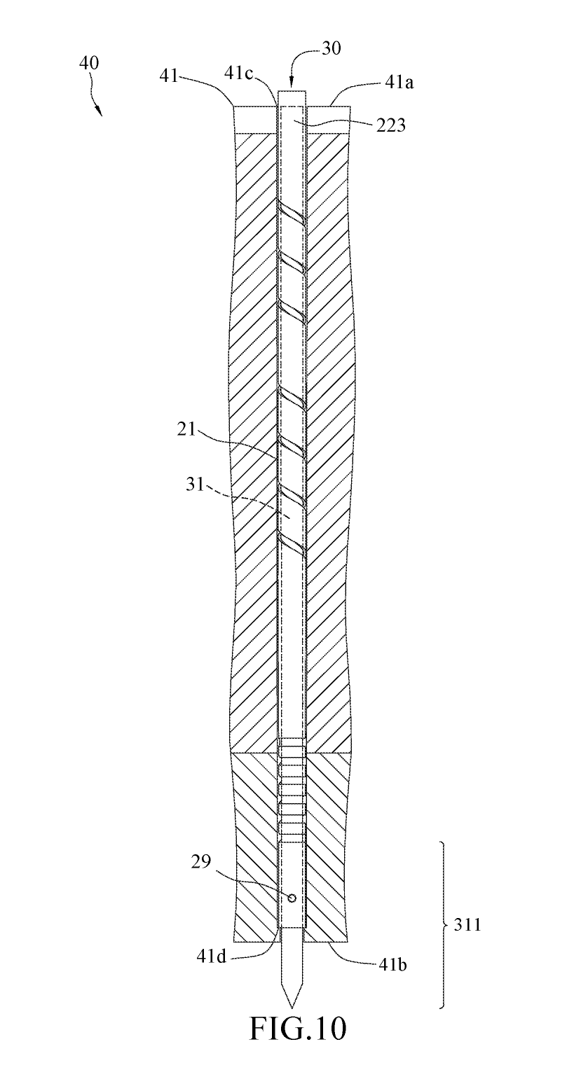

Please refer to FIGS. 10. FIG. 10 illustrates a partial sectional view of a probe device 40 according to a third embodiment of the instant disclosure. The probe device 40 comprises a probe holder 41 and at least one probe structure 30. The probe holder 41 comprises an upper surface 41a, a lower surface 41b, and a guiding channel 41c. The guiding channel 41c is defined through the probe holder 41 from the upper surface 41a to the lower surface 41b. A connection between the guiding channel 41c and the lower surface 41b forms a neck section 41d. When the probe structure 30 is received in the guiding channel 41c, because an outer diameter of the first rigid section 221 of the tube body 21 is greater than an inner diameter of the neck section 41d, the first rigid section 221 is abutted against the neck section 41d and not detached from the guiding channel 41c.

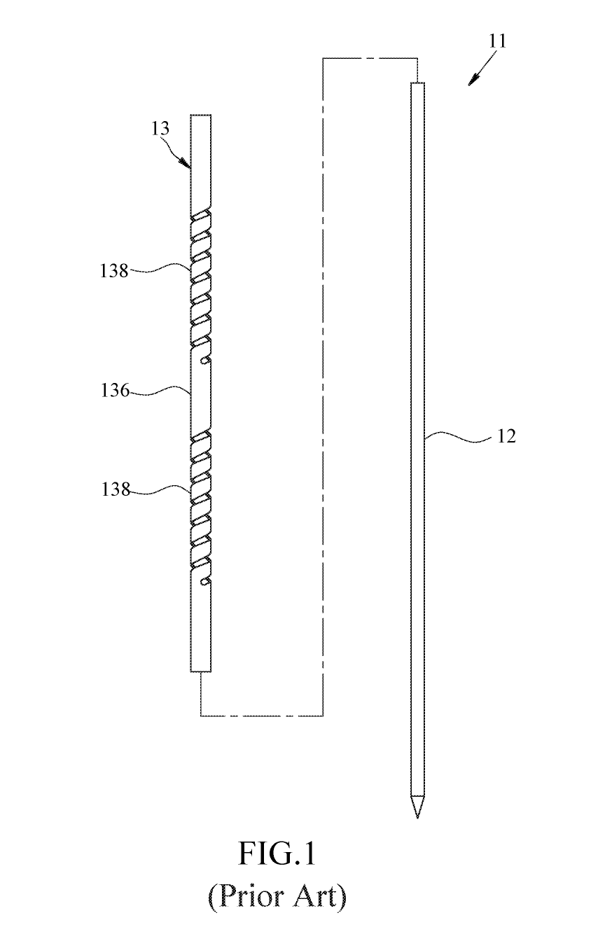

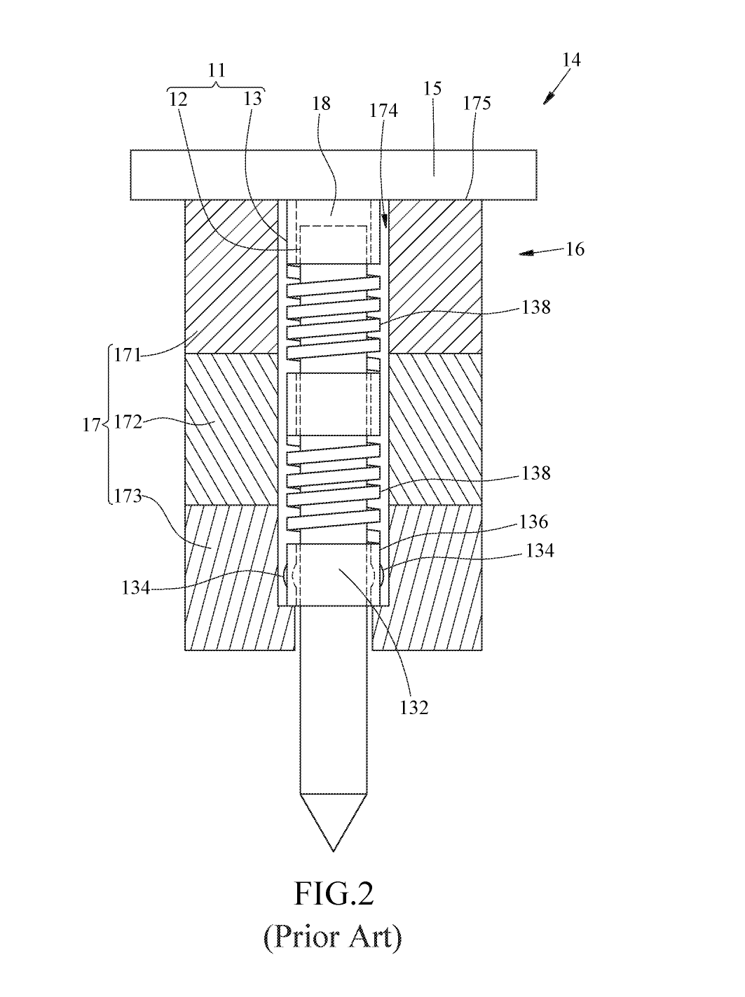

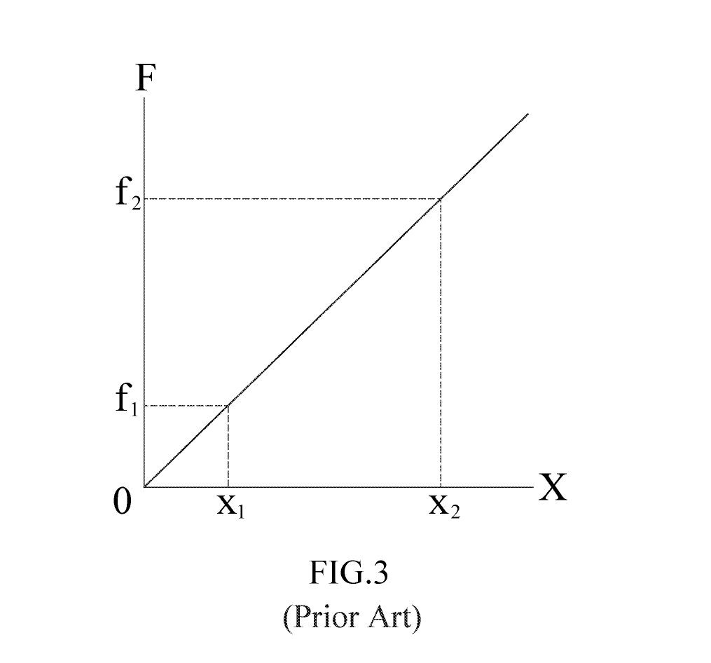

In the testing, as illustrated in FIGS. 1 and 2, a circuit plate 15 is further disposed on the upper surface 41a of the probe holder 41. The probe structure 30 is received in the guiding channel 41c and the probe holder 41 is assembled with the circuit plate 15, and the third rigid section 223 of the tube body 21 is in contact with an electrical contact of the circuit plate 15. When the probe structure 30 is received in the guiding channel 41c, the head section 311 of the pin body 31 is protruding out of the lower surface 41b of the probe holder 41 for probing a component to be tested.

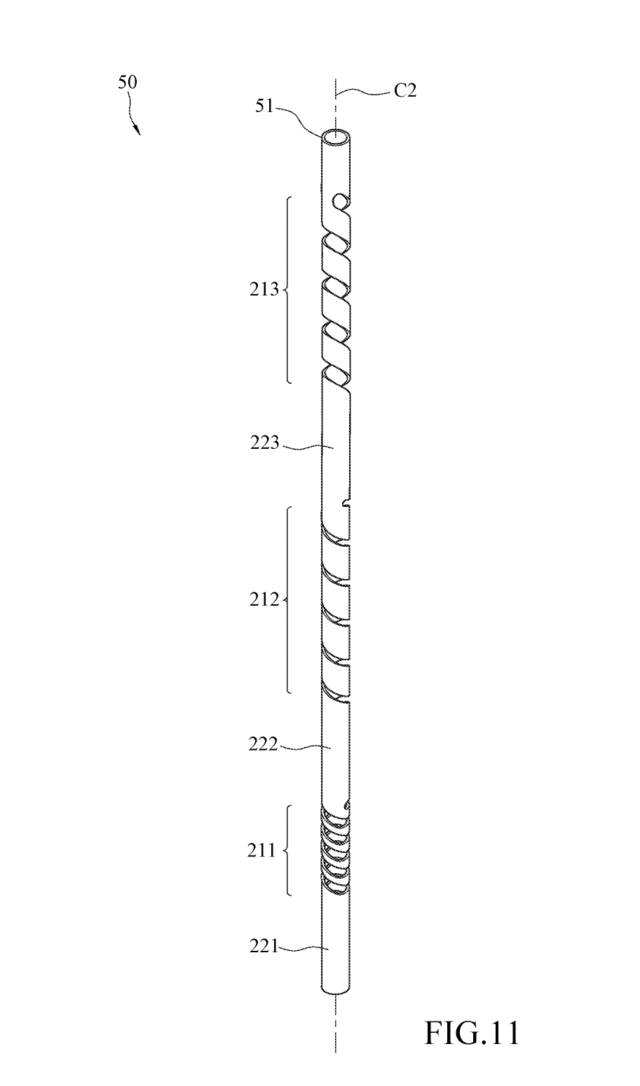

Please refer to FIG. 11. FIG. 11 illustrates a schematic view of a probe structure 50 according to a fourth embodiment of the instant disclosure. As shown in FIG. 11, the probe structure 50 comprises a tube body 51. In this embodiment, in addition to the first rigid section 221, the first spring section 211, the second rigid section 222, the second spring section 212, and the third rigid section 223 provided in the first embodiment, the tube body 51 in the fourth embodiment further comprises a third spring section 213. One of two ends of the third spring section 213 is connected to the third rigid section 223. The third spring section 213 surrounds the central axis C2 and extends in a direction along the central axis C2. One of two ends of the third spring section 213 is connected to the other end of the third rigid section 223. In this embodiment, the spring constant of the third spring section 213 is greater than or equal to the spring constant of the second spring section 212.

It is understood that, the relationship between the spring constant of the first spring section 211 and the second spring section 212 are not limited thereto. For instance, the spring constant K₁ of the first spring section 211 may be greater than the spring constant K₂ of the second spring section 212. In this embodiment, the second spring section 212 comprises a plurality of first curled portions and a plurality of second curled portions, and the first spring section 211 merely comprises a plurality of third curled portions.

In other words, between the first spring section and the second spring section, the spring section with a smaller spring constant comprises a plurality of first curled portions and a plurality of second curled portions, and the spring section with a larger spring constant comprises a plurality of third curled portions. A first distance is between two ends of the first curled portion along the central axis. A second distance is between two ends of the second curled portion along the central axis. The first curled portions and the second curled portions are in a series connection and arranged alternately, and the first distance is less than the second distance.

In the foregoing embodiment, no matter which spring section has smaller spring constant, if a spring section comprises a plurality of first curled portions and a plurality of second curled portions, one end of one of the second curled portions of the spring section is connected to the second rigid section.

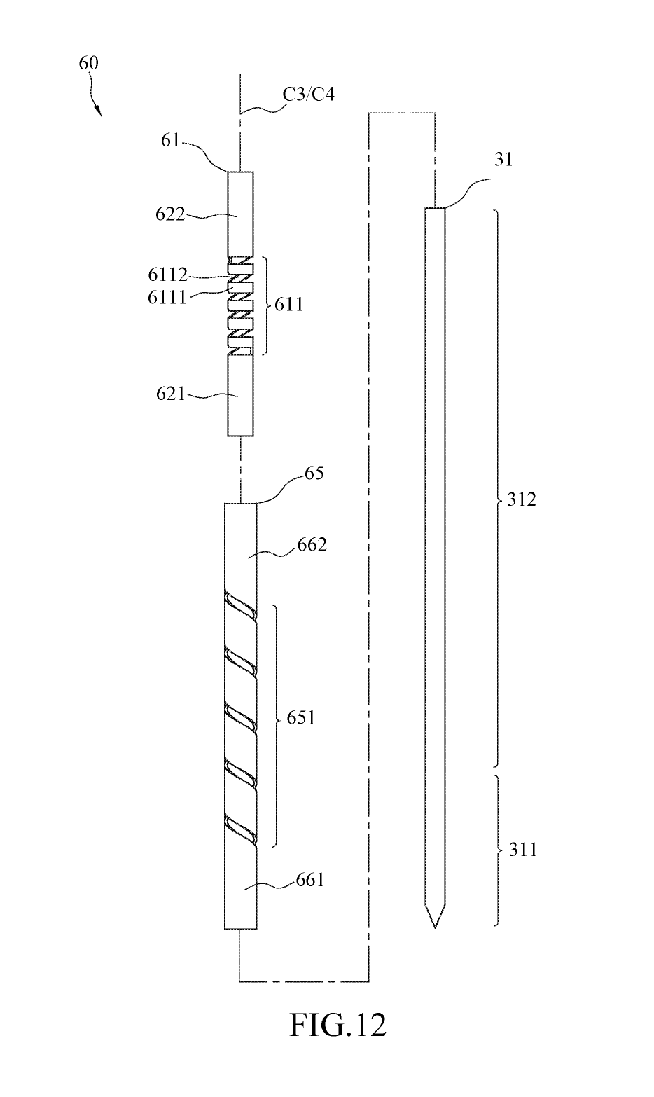

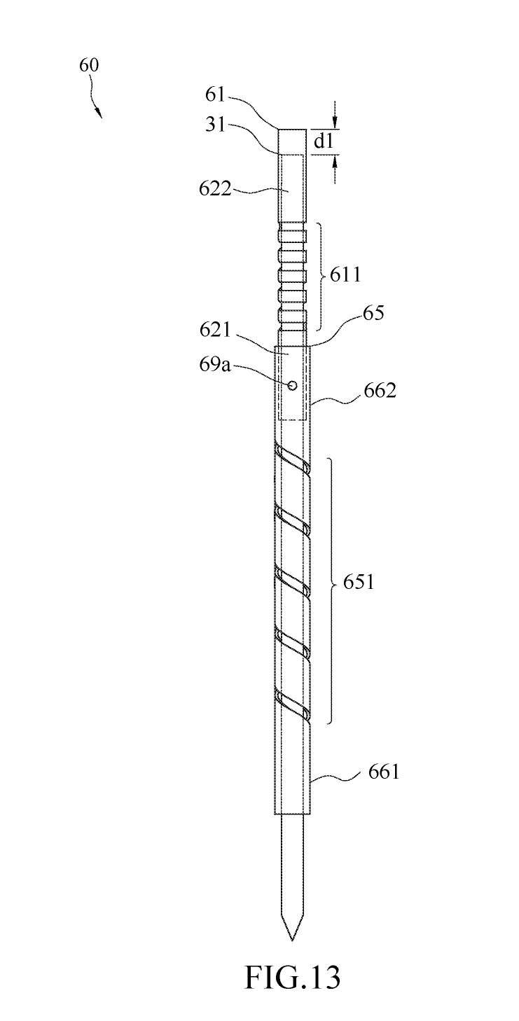

Please refer to FIGS. 12 and 13, respectively illustrate schematic views (1), (2) of a probe structure 60 according to a fifth embodiment of the instant disclosure. In this embodiment, the probe structure 60 comprises a first tube body 61 and a second tube body 65. The first tube body 61 has a central axis C3 and comprises a first rigid section 621, a first spring section 611, and a second rigid section 622. The first spring section 611 surrounds the central axis C3 and extends in a direction along the central axis C3. Two ends of the first spring section 611 are respectively connected to the first rigid section 621 and the second rigid section 622.

Please further refer to FIGS. 12 and 7A. The structure of the first spring section 611 in this embodiment is approximately the same as that of the first spring section 211 in the first embodiment. The first spring section 611 comprises a plurality of first curled portions 6111 and a plurality of second curled portions 6112. The first curled portions 6111 and the second curled portions 6112 are in a series connection and arranged alternately. A first distance between central points at two ends of one of the first curled portions 6111 along the central axis C3 is less than a second distance W2 between central points at two ends of one of the second curled portions 6112 along the central axis C3.

The second tube body 65 has a central axis C4, and an outer diameter of the second tube body 65 is greater than that of the first tube body 61. The second tube body 65 comprises a third rigid section 661, a second spring section 651, and a fourth rigid section 662. Two ends of the second spring section 651 are respectively connected to the third rigid section 661 and the fourth rigid section 662. As shown in FIGS. 12 and 13, the fourth rigid section 662 of the second tube body 65, the first rigid section 621 of the first tube body 61, and the tail section 312 of the pin body 31 are fastened with each other by compression and welding to form a fastening portion 69a. The second spring section 651 surrounds the central axis C4 and extends in a direction along the central axis C4.

In the fifth embodiment, the first tube body 61 is in a series connection with the second tube body 65, and the spring constant of the first spring section 611 of the first tube body 61 is greater than the spring constant of the second spring section 651 of the second tube body 65. For example, the spring constant of the first spring section 611 may be ten times or more over the spring constant of the second spring section 651. In this embodiment, when the probe structure 50 is applied to a testing device (i.e., installed to the testing device), the third rigid section 661 of the second tube body 65 is abutted against a neck section 41d like one shown in FIG. 10.

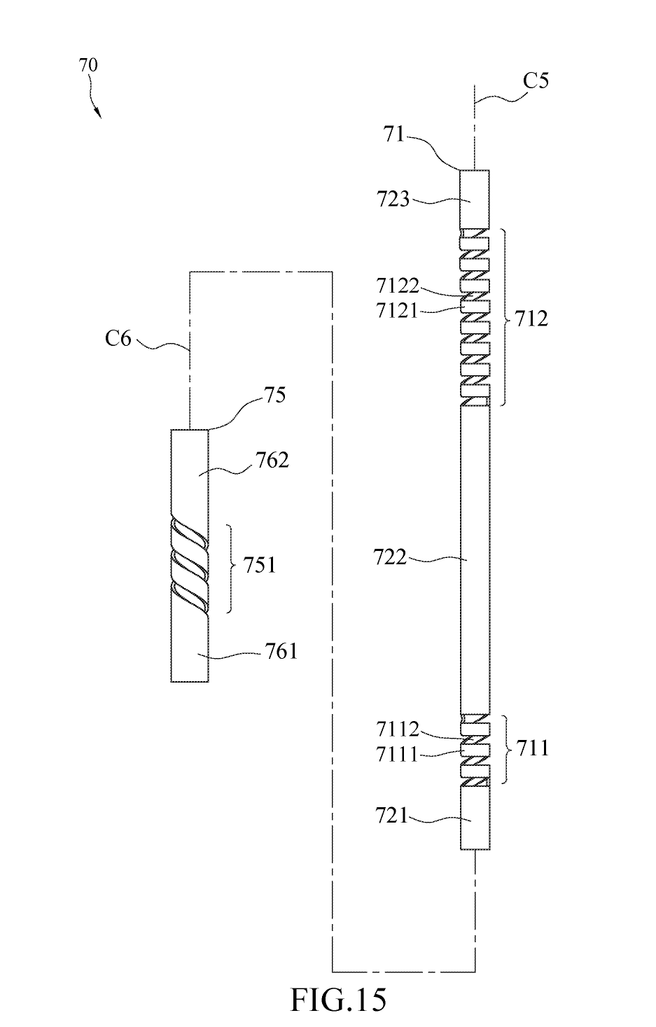

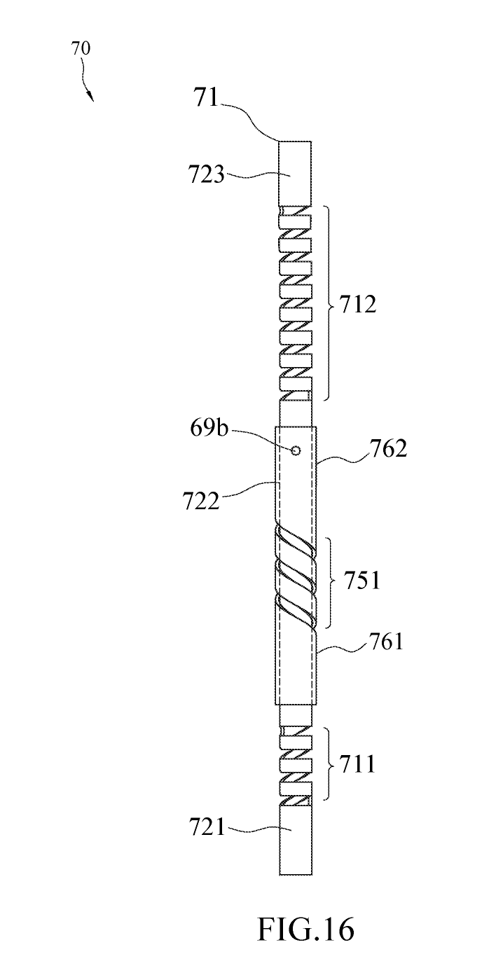

Please refer to FIGS. 15 and 16, respectively illustrate schematic views (1), (2) of a probe structure 70 according to a sixth embodiment of the instant disclosure. The probe structure 70 comprises a first tube body 71 and a second tube body 75. In this embodiment, the first tube body 71 has a central axis C5. The first tube body 71 can be divided into, from one end to the other end, a first rigid section 721, a first spring section 711, a second rigid section 722, a second spring section 712, and a third rigid section 723. The first spring section 711 comprises a plurality of first curled portions 7111 and a plurality of second curled portions 7112. The first curled portions 7111 and the second curled portions 7112 are in a series connection in a head-to-tail manner and arranged alternately to form the first spring section 711. The first spring section 711 surrounds the central axis C5 and extends in a direction along the central axis C5. One of two ends of the first rigid section 721 is connected to one of two ends of the first spring section 711, and the other end of the first rigid section 571 is a free end. Two ends of the second rigid section 722 are respectively connected to the other end of the first spring section 711 and one of two ends of the second spring section 712. One of two ends of the third rigid section 723 is connected to the other end of the second spring section 712, and the other end of the third rigid section 723 is a free end. The details about the first curled portion 7111 and the second curled portion 7112 in the sixth embodiment are approximately similar to that provided in the first embodiment, thus descriptions are omitted.

The turns of the second spring section 712 is different from the turns of the first spring section 711. In this embodiment, the second spring section 712 is shorter than the first spring section 711. The second spring section 712 comprises a plurality of first curled portions 7121 and a plurality of second curled portions 7122. The first curled portions 7121 and the second curled portions 7122 are in a series connection in a head-to-tail manner and arranged alternately to form the second spring section 712. The second spring section 712 surrounds the central axis C5 and extends in the direction along the central axis C5. In this embodiment, the structure of the second spring section 712 is approximately the same as the structure of the first spring section 711, except having different turns. In another case of this embodiment, between the first spring section 711 and the second spring section 712, only one of them has a similar structure with the first spring section 211 in the first embodiment, and the other has a similar structure with the second spring section 212 in the first embodiment.

The second tube body 75 has a central axis C6, and an outer diameter of the second tube body 75 is greater than that of the first tube body 71. The second tube body 75 comprises a fourth rigid section 761, a third spring section 751, and a fifth rigid section 762. The structure of the second tube body 75 in this embodiment is approximately the same as the second tube body 65 in the fifth embodiment.

As shown in FIG. 16, the fifth rigid section 762 of the second tube body 75 and the second rigid section 722 of the first tube body 71 are fastened with each other by compression and welding to form a fastening portion 69b between the third spring section 751 and the second spring section 712. In this embodiment, when the probe structure 70 is applied to the testing device, the fourth rigid section 761 of the second tube body 75 having a greater diameter is abutted against a neck section 41d like one shown in FIG. 10. As illustrated in FIGS. 1 and 2, a circuit plate 15 is electrically connected to a top surface of the third rigid section 723 of the first tube body 71 and compresses the third spring section 751, so that the third spring section 751 is compressed to its dead point or almost to its dead point. During the probe testing step, the first rigid section 721 directly presses on the surface of the pad of a component to be tested, and the first spring section 711 and the second spring section 712 of the first tube body 71 are compressed by the reaction force. In this embodiment, when the first spring section 711 is not in its dead point, the probing signal must be transmitted along the first curled portions 7111 and the second curled portions 7112 orderly. When the first spring section 711 is compressed to its dead point, adjacent first curled portions 7111 are closely in contact with each other. Therefore, the transmission path of the probing signal can be efficiently reduced as compared with a condition the first spring section 711 is not in its dead point. Accordingly, the probe structure 70 can be applied for high frequency signal testing.

In the foregoing embodiments, the tube body may be produced by lithography, and the spring sections are manufactured by exposure and developing procedures. Therefore, the intervals between adjacent spring sections are determined by the procedure parameters of the lithography. Upon having the same lithography procedure parameters, the intervals between adjacent spring sections are substantially the same. Moreover, in all the embodiments, the spring sections are formed by stripe structures (i.e. cross-section of spring section is not circular) rather than the coil spring of the conventional.

As above, the spring section comprising the first curled portions and the second curled portions is adjusted. In other words, the spring section as well as the first curled portions and the second curled portions of the spring section are defined in the embodiments, so that the spring section having proper spring constant can be provided. The spring section may be the first spring sections described in the embodiments, or the spring section may be an spring section comprising the first curled portions and the second curled portions.

While the instant disclosure has been described by the way of example and in terms of the preferred embodiments, it is to be understood that the invention need not be limited to the disclosed embodiments. On the contrary, it is intended to cover various modifications and similar arrangements included within the spirit and scope of the appended claims, the scope of which should be accorded the broadest interpretation so as to encompass all such modifications and similar structures.

What is claimed is:

1. A probe structure, comprising:
a tube body having a central axis, wherein the tube body comprises:
a first rigid section;
a first spring section surrounding the central axis and extending in a direction along the central axis, wherein one of two ends of the first spring section is connected to one end of the first rigid section;
a second rigid section, wherein one of two ends of the second rigid section is connected to the other end of the first spring section; and
a second spring section surrounding the central axis and extending in the direction along the central axis, wherein one of two ends of the second spring section is connected to the other end of the second rigid section, the first spring section and the second spring section are different in spring constant; and
a pin body passing through and disposed in the tube body, wherein the pin body has a head section protruding from the first rigid section, and the head section is fastened to the first rigid section.

2. The probe structure according to claim 1, wherein between the first spring section and the second spring section, the spring section with a smaller spring constant comprises a plurality of first curled portions and a plurality of second curled portions, while the spring section with a larger spring constant comprises a plurality of third curled portions; and wherein a first distance is defined between two ends of one of the first curled portions along the central axis, and a second distance is defined between two ends of one of the second curled portions along the central axis.

3. The probe structure according to claim 2, wherein the first curled portions and the second curled portions are in a series connection and arranged alternately, the first distance is less than the second distance.

4. The probe structure according to claim 3, wherein one end of one of the second curled portions is connected to the second rigid section.

5. The probe structure according to claim 1, wherein the tube body further comprises a third rigid section, one of two ends of the third rigid section is connected to the other end of the second spring section.

6. The probe structure according to claim 5, wherein the tube body further comprises a third spring section surrounding the central axis and extending in the direction along the central axis, one of two ends of the third spring section is connected to the other end of the third rigid section.

7. The probe structure according to claim 2, wherein the first distance is zero.

8. A probe structure, comprising:
a tube body having a central axis, wherein the tube body comprises:
an spring section surrounding the central axis and extending in a direction along the central axis, wherein the spring section comprises a plurality of first curled portions and a plurality of second curled portions, the first curled portions and the second curled portions are in a series connection and arranged alternately, a first distance between two ends of one of the first curled portions along the central axis is less than a second distance between two ends of one of the second curled portions along the central axis.

9. The probe structure according to claim 8, further comprising a second spring section, wherein the spring section is a first spring section, and an spring constant of the second spring section is greater than an spring constant of the first spring section.

10. The probe structure according to claim 8, wherein the first distance is zero.

11. The probe structure according to claim 9, wherein the first distance is zero.

12. The probe structure according to claim 9, further comprising a first rigid section and a second rigid section, the first rigid section is connected to the first spring section, the first spring section is connected to the second rigid section, and the second rigid section is connected to the second spring section.

13. A probe device, comprising:
a probe holder comprising an upper surface, a lower surface, and at least one guiding channel, wherein the guiding channel is defined through the probe holder from the upper surface to the lower surface, a connection between the guiding channel and the lower surface forms a neck section; and
at least one probe structure, comprises:
a tube body having a central axis, wherein the tube body comprises:
a first rigid section;
a first spring section surrounding the central axis and extending in a direction along the central axis, wherein one of two ends of the first spring section is connected to one end of the first rigid section;
a second rigid section, wherein one of two ends of the second rigid section is connected to the other end of the first spring section; and
a second spring section surrounding the central axis and extending in the direction along the central axis, wherein one of two ends of the second spring section is connected to the other end of the second rigid section, the first spring section and the second spring section are different in spring constant; and
a pin body passing through and disposed in the tube body, wherein the pin body has a head section protruding from the first rigid section, and the head section is fastened to the first rigid section;
wherein, the probe structure is received in the guiding channel, an outer diameter of the first rigid section of the tube body is greater than an inner diameter of the neck section, so that the first rigid section is abutted against the neck section, and the head section of the pin body is protruding out of the lower surface.

14. The probe device according to claim 13, wherein between the first spring section and the second spring section, the spring section with a smaller spring constant comprises a plurality of first curled portions and a plurality of second curled portions, while the spring section with a larger spring constant comprises a plurality of third curled portions; and wherein a first distance is defined between two ends of one of the first curled portions along the central axis, and a second distance is defined between two ends of one of the second curled portions along the central axis.

15. The probe device according to claim 14, wherein the first curled portions and the second curled portions are in a series connection and arranged alternately, the first distance is less than the second distance.

16. The probe device according to claim 15, wherein one end of one of the second curled portions is connected to the second rigid section.

17. The probe device according to claim 13, wherein the tube body further comprises a third rigid section, one of two ends of the third rigid section is connected to the other end of the second spring section.

18. The probe device according to claim 17, wherein the tube body further comprises a third spring section surrounding the central axis and extending in the direction along the central axis, one of two ends of the third spring section is connected to the other end of the third rigid section.

19. The probe device according to claim 14, wherein the first distance is zero.
